(19) United States
(12) Patent Application Publication
(10) Pub. No.: US 2026/0215255 A1
(43) Pub. Date: Jul. 23, 2026

(54) SEMICONDUCTOR STRUCTURE AND METHOD OF FABRICATING THE SAME

(71) Applicant: Taiwan Semiconductor Manufacturing Company, Ltd., Hsinchu (TW)

(72) Inventors: Chi-Hui Lai, Taichung City (TW); Yang-Che Chen, Hsin-Chu City (TW); Hsiang-Tai Lu, Hsinchu County (TW); Wei-Ray Lin, Hsinchu City (TW)

(73) Assignee: Taiwan Semiconductor Manufacturing Company, Ltd., Hsinchu (TW)

(21) Appl. No.: 19/034,510

(22) Filed: Jan. 22, 2025

(51) Int. Cl. H01L 23/522; H01L 23/00; H01L 25/065

(52) U.S. Cl. CPC H10W 20/497; H10W 90/00; H10W 80/312; H10W 80/327; H10W 90/293; H10W 90/297; H10W 90/792

(57) ABSTRACT

A semiconductor structure includes a first die and a second die. The first die includes a first substrate, a first interconnection layer, a first inductor pattern and a first bonding layer. The first interconnection layer is disposed on the first substrate. The first inductor pattern is disposed on the first interconnection layer. The first bonding layer includes first bonding pads. The second die is bonded to the first die, and includes a second substrate, a second interconnection layer, a second inductor pattern and a second bonding layer. The second interconnection layer is disposed on the second substrate. The second inductor pattern is disposed on the second interconnection layer. The second bonding layer includes second bonding pads, wherein the second bonding pads are joined with the first bonding pads, and wherein the first inductor pattern is electrically connected to the second inductor pattern through the first and second bonding layers.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 4 are schematic sectional and top views of various stages in a method of fabricating a semiconductor package according to some exemplary embodiments of the present disclosure.

FIG. 5 is a schematic sectional view of a semiconductor structure according to some exemplary embodiments of the present disclosure.

FIG. 6A to FIG. 6D are schematic top view of various inductor pattern designs according to some exemplary embodiments of the present disclosure.

FIG. 7A is a schematic sectional view of a semiconductor package according to some other exemplary embodiments of the present disclosure.

FIG. 7B is an exploded top view of stacked inductor patterns according to the semiconductor package illustrated in FIG. 7A.

FIG. 7C is a three-dimensional view of stacked inductor patterns according to the semiconductor package illustrated in FIG. 7A.

FIG. 8 is a schematic sectional view of a semiconductor structure according to some other exemplary embodiments of the present disclosure.

FIG. 9A is a schematic sectional view of a semiconductor package according to some other exemplary embodiments of the present disclosure.

FIG. 9B is an exploded top view of stacked inductor patterns according to the semiconductor package illustrated in FIG. 9A.

FIG. 9C is a three-dimensional view of stacked inductor patterns according to the semiconductor package illustrated in FIG. 9A.

FIG. 10 is a schematic sectional view of a semiconductor structure according to some other exemplary embodiments of the present disclosure.

FIG. 11 is a schematic sectional view of a semiconductor structure according to some other exemplary embodiments of the present disclosure.

FIG. 12 is a schematic sectional view of a semiconductor structure according to some other exemplary embodiments of the present disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Semiconductor dies may generally include inductor patterns that are placed at the same layer as the conductive pads, whereby the inductor patterns are further located on the interconnection layer. However, the presence of conductive layers/metal layers of the interconnection layer located beneath the inductor patterns will cause a degradation in the inductor performance due to magnetic field/flux, whereby the inductance and quality factor are lowered. On the other hand, removal of the conductive layers/metal layers above and below the inductor patterns may improve inductor performance, but will cause localized pattern density drop which results in a worse plating uniformity and topography. In accordance with some embodiments of the present disclosure, a stacked inductor pattern design is provided to reduce an empty area above and below each inductor pattern to gain inductance, and to mitigate the uniformity/topography problem.

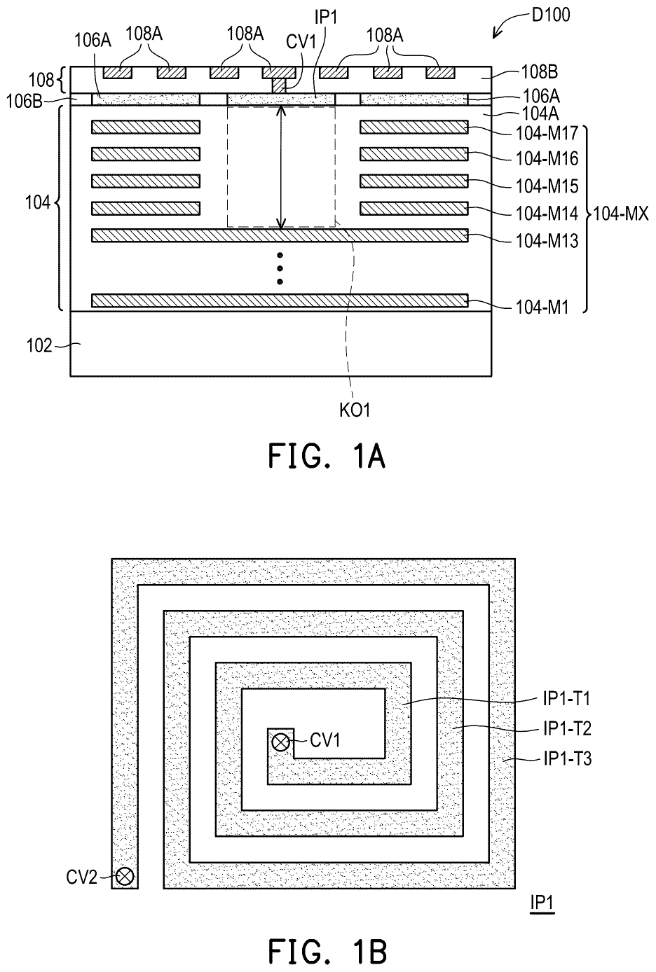

FIG. 1A to FIG. 4 are schematic sectional and top views of various stages in a method of fabricating a semiconductor package according to some exemplary embodiments of the present disclosure. Referring to FIG. 1A and FIG. 1B, in some embodiments, a first die D100 (or a top die) is formed with a first substrate 102, a first interconnection layer 104, a first inductor pattern IP1, first conductive pads 106A, a dielectric layer 106B, and a first bonding layer 108.

In some embodiments, the first substrate 102 may be, for example, a bulk substrate (e.g., a bulk silicon substrate), a silicon-on-insulator (SOI) substrate, or the like. The first substrate 102 may be doped (e.g., with a p-type or an n-type dopant) or undoped. The first substrate 102 may be a wafer, such as a silicon wafer. Generally, the SOI substrate is a layer of a semiconductor material formed on an insulator layer. The insulator layer is, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the first substrate 102 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or combinations thereof.

In some embodiments, the first substrate 102 further includes active components (e.g., transistors or the like) and optionally passive components (e.g., resistors, capacitors, inductors or the like) formed therein. In some other embodiments, the first substrate 102 includes a wide variety of devices disposed thereon. The devices include integrated circuits devices. The devices are, for example, transistors, capacitors, resistors, diodes, photodiodes, fuse devices, or other similar devices. Other devices, such as capacitors, resistors, diodes, photodiodes, fuses and the like may also be formed over the first substrate 102. The functions of the devices may include memory, processors, sensors, amplifiers, power distribution, input/output circuitry, or the like.

As illustrated in FIG. 1A, a first interconnection layer 104 is formed over the first substrate 102. In some embodiments, the formation of the first interconnection layer 104 includes forming a plurality of conductive layers 104-MX and a plurality of dielectric layers 104A that are alternately stacked up along a build-up direction. In one embodiment, the plurality of conductive layers 104-MX includes seventeen layers of conductive layers. The first conductive layer 104-M1 is arranged closest to the first substrate 102, whilst the second conductive layer, the third conductive layer (not shown) up till the seventeenth conductive layer 104-M17 are sequentially formed over the first conductive layer 104-M1. In some embodiments, the first conductive layer 104-M1 may be electrically connected to components (e.g. a transistor) located on the first substrate 102. Furthermore, the plurality of conductive layers 104-MX may be electrically connected to one another through a plurality of conductive vias (not shown). In certain embodiments, the dielectric layers 104A are surrounding and covering the conductive layers 104-MX.

In some embodiments, a material of the dielectric layers 104A may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layers 104A are formed by suitable fabrication techniques such as spin-on coating, chemical vapor deposition (CVD), plasma-enhanced chemical vapor deposition (PECVD) or the like. The disclosure is not limited thereto.

In some embodiments, a material of the conductive layers 104-MX (and conductive vias) may include conductive materials formed by electroplating or deposition, such as aluminum, titanium, copper, nickel, tungsten, and/or alloys thereof, which may be patterned using a photolithography and etching process. In some embodiments, the conductive layers 104-MX (and conductive vias) may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, the first interconnection layer 104 is formed with a first keep out zone KO1 that is free of the plurality of conductive layers 104-MX. For example, in the exemplary embodiment, a height of the first keep out zone KO1 is equal to or greater than a total height of four conductive layers (e.g. the fourteenth conductive layer 104-M14, the fifteenth conductive layer 104-M15, the sixteenth conductive layer 104-M16 and the seventeenth conductive layer 104-M17). In some embodiments, the first keep out zone KO1 is a region located below the first inductor pattern IP1 whereby at least four conductive layers in the plurality of conductive layers 104-MX are absent (or not formed). The height of the first keep out zone KO1 may be measured from a bottom surface of the first inductor pattern IP1 to a top surface of a nearest conductive layer (e.g. the thirteenth conductive layer 104-M13) vertically located underneath. For example, the height of the first keep out zone KO1 may be at least 6 μm, or more than 6 μm. Although seventeen conductive layers 104-MX are illustrated herein, it is noted that a number of the conductive layers 104-MX is not limited thereto, and may be adjusted based on design requirements. In some other embodiments, the number of the conductive layers 104-MX is appropriately adjusted as long as a first keep out zone KO1 is maintained in the first interconnection layer 104.

As further illustrated in FIG. 1A, a plurality of conductive pads 106A and the first inductor pattern IP1 are formed on the first interconnection layer 104. For example, the conductive pads 106A and the first inductor pattern IP1 are formed in the same steps by forming a conductive layer (not shown), and patterning or etching the conductive layer to form the conductive pads 106A and the first inductor pattern IP1. In some embodiments, the conductive pads 106A and the first inductor pattern IP1 are electrically connected to the first interconnection layer 104 through a plurality of conductive vias (not shown). Furthermore, the first inductor pattern IP1 is formed on the first interconnection layer 104 so that the first inductor pattern IP1 is arranged above the first keep out zone KO1.

As illustrated in a top view of the first inductor pattern IP1 shown in FIG. 1B, in some embodiments, the first inductor pattern IP1 is a spiral inductor pattern having a rectangular shape. For example, in one embodiment, the first inductor pattern IP1 contains three coil turns including a first coil turn IP1-T1, a second coil turn IP1-T2 joined with the first coil turn IP1-T1, and a third coil turn IP1-T3 joined with the second coil turn IP1-T2. Although three coil turns are illustrated herein, it is noted that the number of coil turns in the first inductor pattern IP1 is not particularly limited, and can be appropriately adjusted as long as the number of coil turns is more than one. In some embodiments, a terminal of the first coil turn IP1-T1 (the inner coil turn) is connected to a conductive via CV1, while a terminal of the third coil turn IP1-T3 (the outer coil turn) is connected to a conductive via CV2. For example, the conductive via CV1 is electrically connected to one first bonding pad 108A of the first bonding layer 108, while the conductive via CV2 is electrically connected to the seventeenth conductive layer 104-M17 in the first interconnection layer 104. After forming the conductive pads 106A and the first inductor pattern IP1, the dielectric layer 106B is formed to laterally surround the conductive pads 106A and the first inductor pattern IP1.

In a subsequent step, the first bonding layer 108 is formed over the dielectric layer 106B, whereby forming the first bonding layer 108 includes forming a plurality of first bonding pads 108A, and a first bonding film 108B surrounding the first bonding pads 108A. For example, the first bonding pads 108A are formed using a suitable technique such as damascene, dual-damascene, plating, deposition, the like, or combinations thereof. In some embodiments, the first bonding pads 108A are formed of conductive materials such as copper, or the like. Furthermore, the conductive via CV1 is directly joining one of the first bonding pads 108A to the first inductor pattern IP1. In some embodiments, a material of the first bonding film 108B is similar to a material of the dielectric layers 104A, thus details of the first bonding film 108B will be omitted herein.

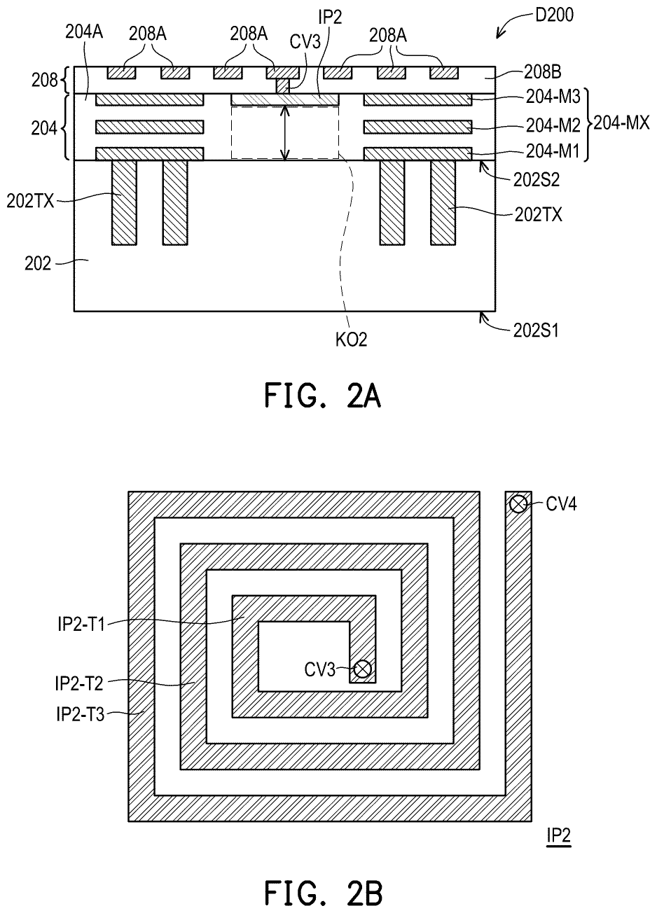

Referring to FIG. 2A and FIG. 2B, in some embodiments, a second die D200 (or an interposer die) is formed with a second substrate 202, through substrate vias 202TX, a second interconnection layer 204, a second inductor pattern IP2, and a second bonding layer 208.

In some embodiments, the second substrate 202 may be, for example, a bulk substrate (e.g., a bulk silicon substrate), a silicon-on-insulator (SOI) substrate, or the like. The second substrate 202 may be doped (e.g., with a p-type or an n-type dopant) or undoped. The second substrate 202 may be a wafer, such as a silicon wafer. Generally, the SOI substrate is a layer of a semiconductor material formed on an insulator layer. The insulator layer is, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the second substrate 202 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or combinations thereof.

In some embodiments, the second substrate 202 further includes active components (e.g., transistors or the like) and optionally passive components (e.g., resistors, capacitors, inductors or the like) formed therein. In some other embodiments, the second substrate 202 includes a wide variety of devices disposed thereon. The devices include integrated circuits devices. The devices are, for example, transistors, capacitors, resistors, diodes, photodiodes, fuse devices, or other similar devices. Other devices, such as capacitors, resistors, diodes, photodiodes, fuses and the like may also be formed over the second substrate 202. The functions of the devices may include memory, processors, sensors, amplifiers, power distribution, input/output circuitry, or the like. Furthermore, in some embodiments, the second substrate 202 includes a first surface 202S1 and a second surface 202S2 opposite to the first surface 202S1. In some embodiments, through substrate vias 202TX are embedded in the second substrate 202, and a top surface of the through substrate vias 202TX is revealed at the second surface 202S2.

As further illustrated in FIG. 2A, a second interconnection layer 204 is formed on the second surface 202S2 of the second substrate 202. In some embodiments, the formation of the second interconnection layer 204 includes forming a plurality of conductive layers 204-MX and a plurality of dielectric layers 204A that are alternately stacked up along a build-up direction. In the exemplary embodiment, the plurality of conductive layers 204-MX includes three conductive layers such as a first conductive layer 204-M1, a second conductive layer 204-M2 and a third conductive layer 204-M3. In some embodiments, the first conductive layer 204-M1 is electrically connected to the through substrate vias 202TX in the second substrate 202, or may be electrically connected to components (e.g. a transistor) located on the second substrate 202. Furthermore, the plurality of conductive layers 204-MX may be electrically connected to one another through a plurality of conductive vias (not shown). In certain embodiments, the dielectric layers 204A are surrounding and covering the conductive layers 204-MX.

In some embodiments, a material of the dielectric layers 204A may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layers 204A are formed by suitable fabrication techniques such as spin-on coating, chemical vapor deposition (CVD), plasma-enhanced chemical vapor deposition (PECVD) or the like. The disclosure is not limited thereto.

In some embodiments, a material of the conductive layers 204-MX (and conductive vias) may include conductive materials formed by electroplating or deposition, such as aluminum, titanium, copper, nickel, tungsten, and/or alloys thereof, which may be patterned using a photolithography and etching process. In some embodiments, the conductive layers 204-MX (and conductive vias) may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, the second interconnection layer 204 is formed with a second keep out zone KO2 that is free of the plurality of conductive layers 204-MX. For example, in the exemplary embodiment, a height of the second keep out zone KO2 is equal to or greater than a total height of two conductive layers (e.g. the first conductive layer 204-M1, and the second conductive layer 204-M2) of the plurality of second conductive layers 204-MX. In some alternative embodiments, a height of the second keep out zone KO2 is equal to or greater than a height of one conductive layer of the plurality of second conductive layers 204-MX. In some embodiments, the second keep out zone KO2 is a region located below the second inductor pattern IP2 whereby at least one conductive layer in the plurality of conductive layers 204-MX are absent (or not formed). The height of the second keep out zone KO2 may be measured from a bottom surface of the second inductor pattern IP2 to a top surface of a nearest conductive layer vertically located underneath (if present), or to a bottom surface of the second interconnection layer 204. Although three conductive layers 204-MX are illustrated herein, it is noted that a number of the conductive layers 204-MX is not limited thereto, and may be adjusted based on design requirements. In some other embodiments, the number of the conductive layers 204-MX is appropriately adjusted as long as a second keep out zone KO2 is maintained in the second interconnection layer 204.

As further illustrated in FIG. 2A, in some embodiments, the second inductor pattern IP2 is formed on the second interconnection layer 204, and is surrounded by the dielectric layers 204A. In some embodiments, the second inductor pattern IP2 is formed to be levelled with the third conductive layer 204-M3, and located on the second keep out zone KO2 of the second interconnection layer 204. As illustrated in a top view of the second inductor pattern IP2 shown in FIG. 2B, in some embodiments, the second inductor pattern IP2 is a spiral inductor pattern having a rectangular shape. For example, in one embodiment, the second inductor pattern IP2 contains three coil turns including a first coil turn IP2-T1, a second coil turn IP2-T2 joined with the first coil turn IP2-T1, and a third coil turn IP2-T3 joined with the second coil turn IP2-T2. Although three coil turns are illustrated herein, it is noted that the number of coil turns in the second inductor pattern IP2 is not particularly limited, and can be appropriately adjusted as long as the number of coil turns is more than one. In some embodiments, a terminal of the first coil turn IP2-T1 (the inner coil turn) is connected to a conductive via CV3, while a terminal of the third coil turn IP2-T3 (the outer coil turn) is connected to a conductive via CV4. For example, the conductive via CV3 is electrically connected to one second bonding pad 208A of the second bonding layer 208, while the conductive via CV 4 is electrically connected to the second conductive layer 204-M2 in the second interconnection layer 204. In some embodiments, a material of the second inductor pattern IP2 is different from a material of the first inductor pattern IP1. For example, in one embodiment, the material of the second inductor pattern IP2 is copper, while the material of the first inductor pattern IP1 is aluminum. In some alterative embodiments, the material of the second inductor pattern IP2 is the same as the material of the first inductor pattern IP1, and are for example, both made of copper.

After forming the second interconnection layer 204 and the second inductor pattern IP2, the second bonding layer 208 is formed on the second interconnection layer 204. In some embodiments, forming the second bonding layer 208 includes forming a plurality of second bonding pads 208A, and a second bonding film 208B surrounding the second bonding pads 208A. For example, the second bonding pads 208A are formed using a suitable technique such as damascene, dual-damascene, plating, deposition, the like, or combinations thereof. In some embodiments, the second bonding pads 208A are formed of conductive materials such as copper, or the like. Furthermore, the conductive via CV3 is directly joining one of the second bonding pads 208A to the second inductor pattern IP2. In some embodiments, a material of the second bonding film 208B is similar to a material of the dielectric layers 104A, thus details of the second bonding film 208B will be omitted herein.

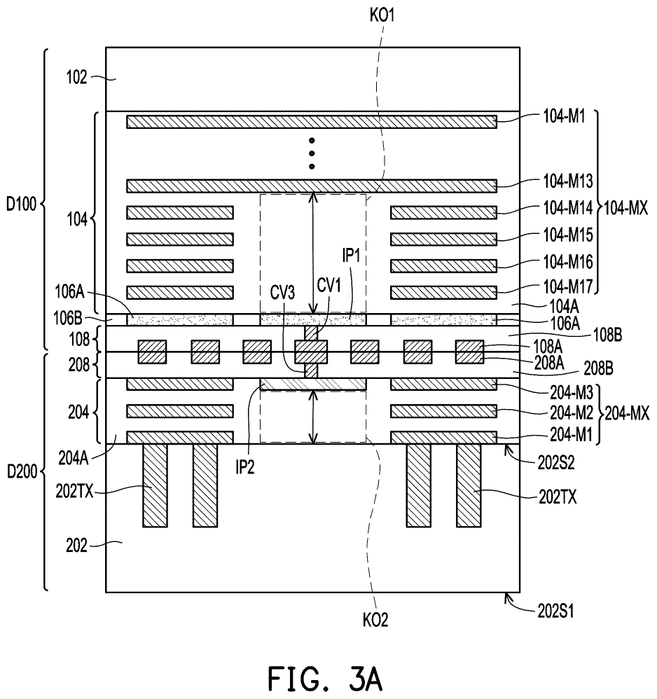

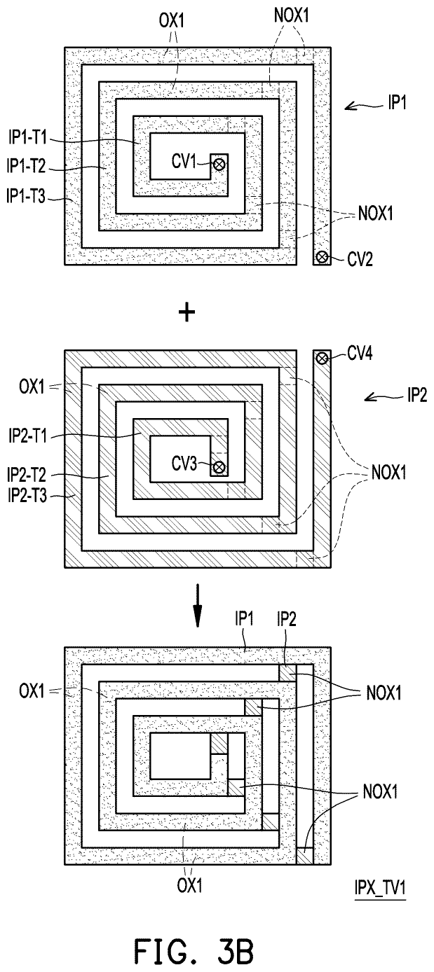

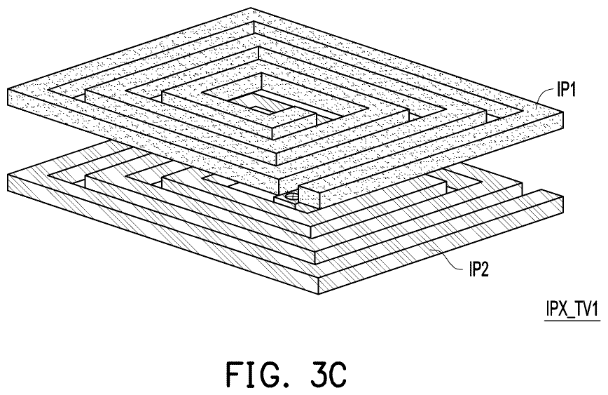

Referring to FIG. 3A, after forming the first die D100 and the second die D200, the first die D100 is bonded to the second die D200 using dielectric-to-dielectric bonding and direct metal-to-metal bonding. In some embodiments, the first die D100 is singulated prior to bonding to the second die D200. In some embodiments, the first bonding layer 108 is directly joined to the second bonding layer 208, whereby the first bonding pads 108A are bonded to the second bonding pads 208A, and the first bonding film 108B is bonded to the second bonding film 208B. In the exemplary embodiment, the first inductor pattern IP1 is electrically connected to the second inductor pattern IP2 through the conductive via CV1, the first bonding pad 108A, the second bonding pad 208A and the conductive via CV3. As such, a stacked inductor pattern can be formed.

FIG. 3B is an exploded top view of stacked inductor patterns according to the package structure illustrated in FIG. 3A. FIG. 3C is a three-dimensional view of stacked inductor patterns according to the package structure illustrated in FIG. 3A. As shown in FIG. 3A to FIG. 3C, the first inductor pattern IP1 is stacked over the second inductor pattern IP2 to form a stacked inductor pattern IPX_TV1. For example, the first inductor pattern IP1 and the second inductor pattern IP2 are partially overlapped with one another to include overlapping regions OX1 and non-overlapping regions NOX1. The regions where the first inductor pattern IP1 and the second inductor pattern IP2 are overlapped with one another in the stacking direction are defined as the overlapping regions OX1, while the regions where the first inductor pattern IP1 and the second inductor pattern IP2 are non-overlapped with one another in the stacking direction are defined as the non-overlapping regions NOX1. In some embodiments, the first inductor pattern IP1 and the second inductor pattern IP2 are both spiral inductor patterns having a rectangular shape, whereby sidewalls of the first inductor pattern IP1 are aligned with sidewalls of the second inductor pattern IP2. However, a starting point and ending point of the terminals of the first inductor pattern IP1 are different from a starting point and ending point of the terminals of the second inductor pattern IP2. In other words, the first inductor pattern IP1 and the second inductor pattern IP2 may have the same number of coil turns, but an arrangement of the terminals of the first inductor pattern IP1 are shifted from an arrangement of the terminals of the second inductor pattern IP2. In some embodiments, a thickness of the first inductor pattern IP1 is different from a thickness of the second inductor pattern IP2. For example, the thickness of the first inductor pattern IP1 is greater than the thickness of the second inductor pattern IP2. However, the disclosure is not limited thereto, and in some other embodiments, the thickness of the first inductor pattern IP1 is the same as the thickness of the second inductor pattern IP2, or may be smaller than the thickness of the second inductor pattern IP2. In certain embodiments, the thickness of the first inductor pattern IP1 and the second inductor pattern IP2 may be adjusted based on product requirements.

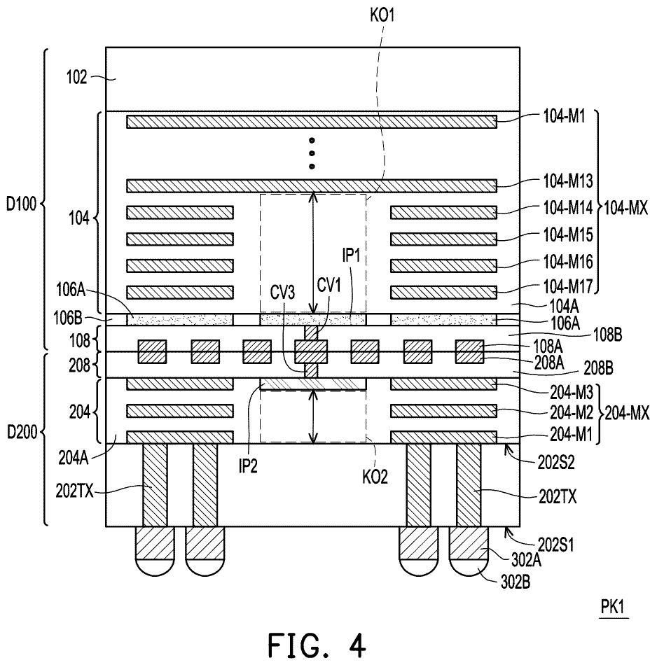

Referring to FIG. 4, in a subsequent step, a thinning process is performed to the second substrate 202 of the second die D200 until the through substrate vias 202TX are exposed on the first surface 202S1. In some embodiments, the thinning process may include a back-grinding process, a polishing process or an etching process. After revealing the through substrate vias 202TX on the second substrate 202, conductive posts 302A and conductive terminals 302B are then formed on the first surface 202S1 of the second substrate 202. In some embodiments, the conductive posts 302A and conductive terminals 302B are disposed on and electrically connected to the through substrate vias 202TX. In certain embodiments, the conductive posts 302A and conductive terminals 302B are also electrically connected to the components embedded in the second substrate 202 of the second die D200. In some embodiments, the conductive posts 302A include conductive materials such as copper, or the like. Furthermore, the conductive terminals 302B are formed on and electrically connected to the conductive post 302A. In some embodiments, the conductive terminals 302B are micro-bumps, such as micro-bumps having copper metal pillars. In some alternative embodiments, the conductive terminals 302B are solder bumps, lead-free solder bumps, or micro bumps, such as controlled collapse chip connection (C4) bumps or micro bumps containing copper pillars. After forming the conductive post 302A and the conductive terminals 302B on the second substrate 202, the stacked structure may be singulated to form individual semiconductor packages. For example, the singulation process is, for example, a laser cutting process, a mechanical sawing process, or other suitable processes. Up to here, a semiconductor package PK1 in accordance with some embodiments of the present disclosure is accomplished.

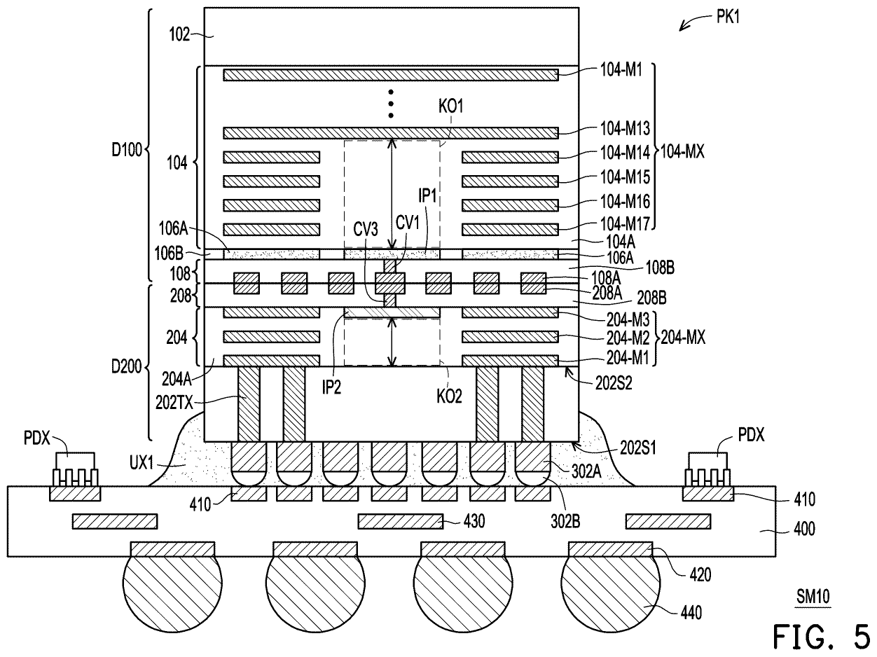

FIG. 5 is a schematic sectional view of a semiconductor structure according to some exemplary embodiments of the present disclosure. Referring to FIG. 5, in some embodiments, the semiconductor package PK1 obtained in FIG. 4 is mounted or attached onto a circuit substrate 400 through the conductive terminals 302B. In some embodiments, the circuit substrate 400 includes contact pads 410, contact pads 420, metallization layers 430, and vias (not shown). In some embodiments, the contact pads 410 and the contact pads 420 are respectively distributed on two opposite sides of the circuit substrate 400, and are exposed for electrically connecting with later-formed elements/features. In some embodiments, the metallization layers 430 and the vias are embedded in the circuit substrate 400 and together provide routing function for the circuit substrate 400, wherein the metallization layers 430 and the vias are electrically connected to the contact pads 410 and the contact pads 420. In other words, at least some of the contact pads 410 are electrically connected to some of the contact pads 420 through the metallization layers 430 and the vias. In some embodiments, the contact pads 410 and the contact pads 420 may include metal pads or metal alloy pads. In some embodiments, the materials of the metallization layers 430 and the vias may be substantially the same or similar to the material of the contact pads 410 and the contact pads 420.

Furthermore, in some embodiments, the semiconductor package PK1 is bonded to the circuit substrate 400 through physically connecting the conductive terminals 302B and the contact pads 410 to form a stacked structure. In certain embodiments, the semiconductor package PK1 is electrically connected to the circuit substrate 400. In some embodiments, the circuit substrate 400 is such as an organic flexible substrate or a printed circuit board. In such embodiments, the conductive terminals 302B are, for example, chip connectors. In some embodiments, a plurality of conductive balls 440 are respectively formed on the substrate 400. As illustrated in FIG. 5, for example, the conductive balls 440 are connected to the contact pads 420 of the circuit substrate 400. In other words, the conductive balls 440 are electrically connected to the circuit substrate 400 through the contact pads 420. Through the contact pads 410 and the contact pads 420, some of the conductive balls 440 are electrically connected to the first die D100 and/or the second die D200 of the semiconductor package PK1. In some embodiments, the conductive balls 440 are, for example, solder balls or ball grid array (BGA) balls.

In addition, as illustrated in FIG. 5, passive devices PDX (integrated passive device or surface mount devices) may be mounted on the circuit substrate 400. For example, the passive devices PDX may be mounted on the contact pads 410 of the circuit substrate 400 through a soldering process. The disclosure is not limited thereto. In certain embodiments, the passive devices PDX may be mounted on the circuit substrate 400 to surround the semiconductor package PK1. As further illustrated in FIG. 5, in some embodiments, an underfill structure UX1 is formed to fill up the spaces in between the circuit substrate 400 and the semiconductor package PK1. In certain embodiments, the underfill structure UX1 fills up the spaces in between adjacent conductive post 302A and conductive terminals 302B and covers the conductive post 302A and the conductive terminals 302B. In some embodiments, the passive devices PDX is exposed by the underfill structure UX1, and kept a distance apart from the underfill structure UX1. In other words, the underfill structure UX1 does not cover the passive devices PDX. After bonding the semiconductor package PK1 on the circuit substrate 400 and forming the underfill structure UX1, a semiconductor structure SM10 in accordance with some embodiments of the present disclosure is accomplished.

In the semiconductor package PK1 and the semiconductor structure SM10 of the present disclosure, since a second inductor pattern IP2 is electrically connected to the first inductor pattern IP1, and the first and second inductor patterns IP1, IP2 are stacked together to from a stacked inductor pattern, the inductance can be increased without excessive area sacrifice from the removal of the conductive layers/metal layers above and below the inductor pattern. In other words, the presence of the second inductor pattern IP2 may occupy the originally empty area to gain inductance, which may also mitigate the uniformity/topography problem.

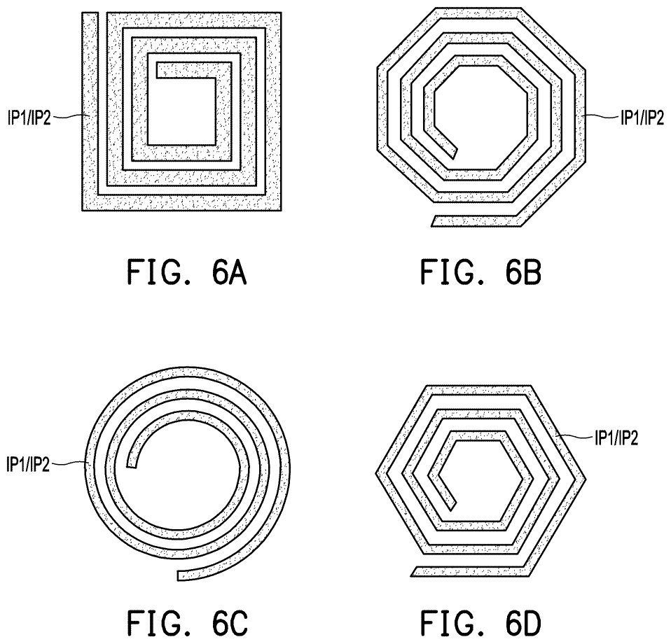

FIG. 6A to FIG. 6D are schematic top view of various inductor pattern designs according to some exemplary embodiments of the present disclosure. In the previous embodiments, the first inductor pattern IP1 and the second inductor pattern IP2 are spiral inductor patterns having a rectangular shape. However, the disclosure is not limited thereto. In various embodiments, the first inductor pattern IP1 and the second inductor pattern IP2 are spiral inductor patterns having a rectangular shape or square shape as shown in FIG. 6A, are spiral inductor patterns having an octagonal shape as shown in FIG. 6B, are spiral inductor patterns having a circular shape as shown in FIG. 6C, or are spiral inductor patterns having a hexagonal shape as shown in FIG. 6D. In other words, the first inductor pattern IP1 and the second inductor pattern IP2 may have the same shape pattern, but a shape of the first and second inductor patterns IP1, IP2 are not particularly limited, and may be adjusted based on design requirements. Furthermore, the various inductor pattern designs illustrated in FIG. 6A to FIG. 6D may be applied to any of the inductor patterns described throughout the present disclosure.

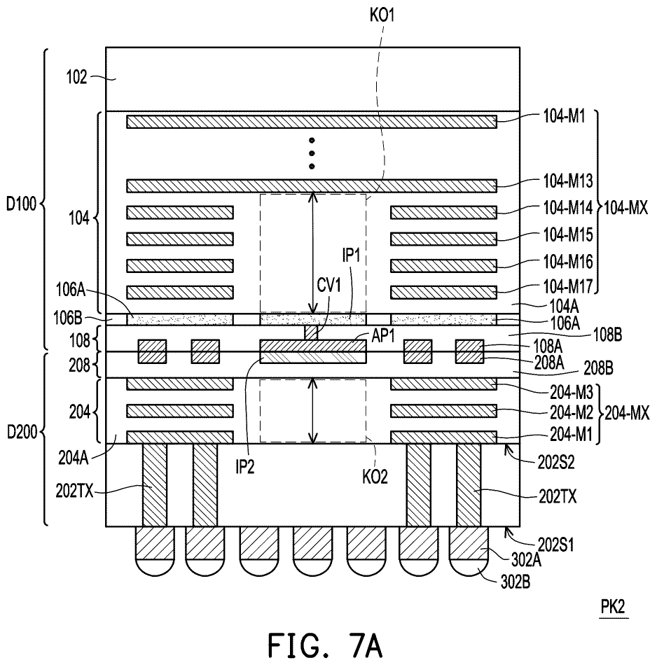

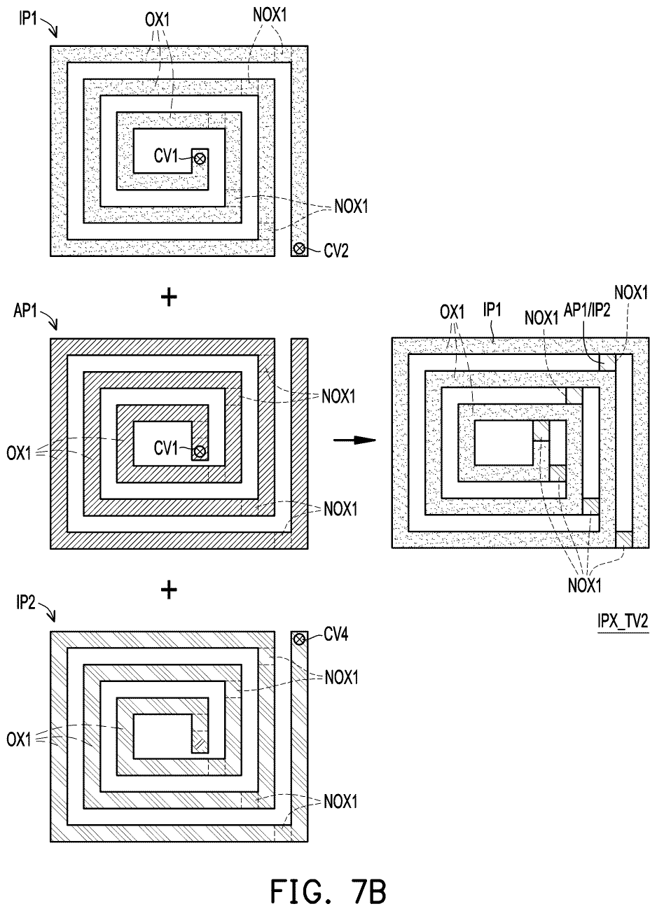

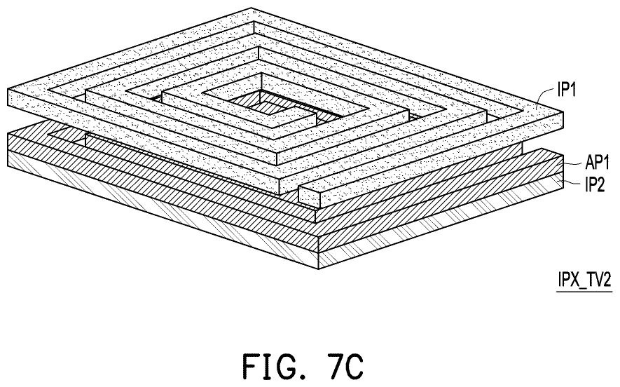

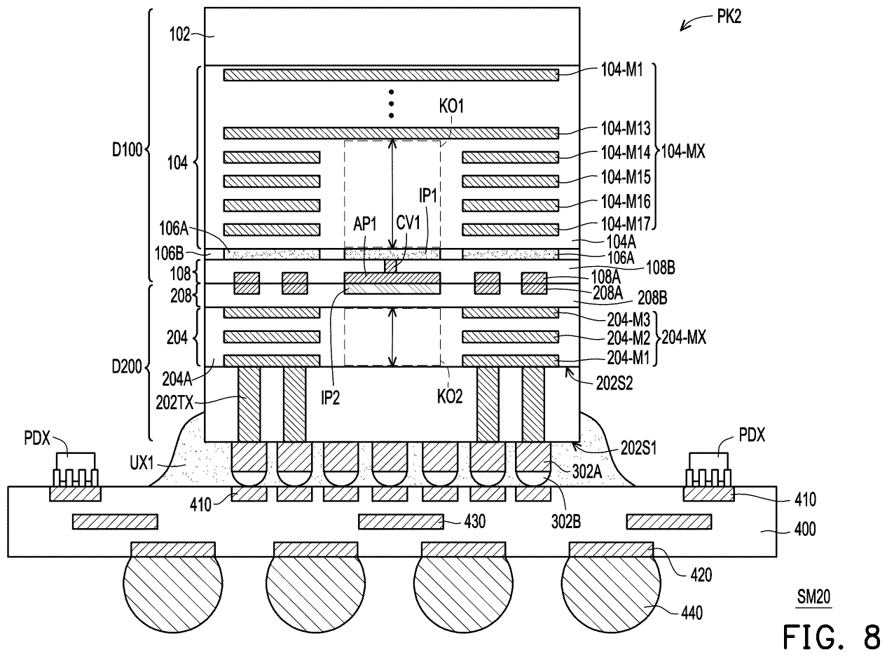

FIG. 7A is a schematic sectional view of a semiconductor package according to some other exemplary embodiments of the present disclosure. FIG. 7B is an exploded top view of stacked inductor patterns according to the semiconductor package illustrated in FIG. 7A. FIG. 7C is a three-dimensional view of stacked inductor patterns according to the semiconductor package illustrated in FIG. 7A. The semiconductor package PK2 and the stacked inductor pattern IPX_TV2 illustrated in FIG. 7A to FIG. 7C are similar to the semiconductor package PK1 and the stacked inductor pattern IPX_TV1 illustrated in FIG. 4 and FIG. 3B to FIG. 3C. Therefore, the same reference numerals are used to refer to the same or liked parts, and its detailed description will be omitted herein. The difference between the embodiments is in the arrangement of the inductor patterns (IP1, IP2) and the presence of an auxiliary inductor pattern AP1.

As illustrated in FIG. 7A to FIG. 7C, in some embodiments, the first bonding layer 108 in the first die D100 further includes an auxiliary inductor pattern AP1 that is joined with the first inductor pattern IP1. For example, the auxiliary inductor pattern AP1 is levelled with the first bonding pads 108A in the first bonding layer 108, and are made of the same materials with the first bonding pads 108A. In the exemplary embodiment, the conductive via CV1 is electrically connecting the first inductor pattern IP1 to the auxiliary inductor pattern AP1. Furthermore, the conductive via CV2 is electrically connecting the first inductor pattern IP1 to the seventeenth conductive layer 104-M17 in the first interconnection layer 104.

In some embodiments, the second inductor pattern IP2 is embedded in the second bonding layer 208 in the second die D200. For example, the second inductor pattern IP2 is located aside and levelled with the second bonding pads 208A, and are made of the same materials with the second bonding pads 208A. In the exemplary embodiment, the first die D100 is bonded to the second die D200 so that the auxiliary inductor pattern AP1 is directly bonded to the second inductor pattern IP2 using direct metal-to-metal bonding. Furthermore, the conductive via CV4 is electrically connecting the second inductor pattern IP2 to the third conductive layer 204-M3 in the second interconnection layer 204. In some embodiments, the auxiliary inductor pattern AP1 and the second inductor pattern IP2 have the same inductor pattern design. In one embodiment, the auxiliary inductor pattern AP1 is fully overlapped with the second inductor pattern IP2 in the stacking direction. For example, the coil turns and terminals of the auxiliary inductor pattern AP1 and the second inductor pattern IP2 are matched and aligned with one another.

As further illustrated in FIG. 7B, the first inductor pattern IP1 are partially overlapped with the auxiliary inductor pattern AP1 and the second inductor pattern IP2 to include overlapping regions OX1 and non-overlapping regions NOX1. The regions where the first inductor pattern IP1 are overlapped with the auxiliary inductor pattern AP1 and the second inductor pattern IP2 in the stacking direction are defined as the overlapping regions OX1, while the regions where the first inductor pattern IP1 are non-overlapped with the auxiliary inductor pattern AP1 and the second inductor pattern IP2 are defined as the non-overlapping regions NOX1. In some embodiments, the first inductor pattern IP1, the auxiliary inductor pattern AP1 and the second inductor pattern IP2 are all spiral inductor patterns having a rectangular shape, whereby sidewalls of the first inductor pattern IP1, the auxiliary inductor pattern AP1 and the second inductor pattern IP2 are aligned with one another. However, a starting point and ending point of the terminals of the first inductor pattern IP1 are different from a starting point and ending point of the terminals of the auxiliary inductor pattern AP1 and the second inductor pattern IP2. As such, the first inductor pattern IP1, the auxiliary inductor pattern AP1 and the second inductor pattern IP2 are stacked over one another along the stacking direction to form the stacked inductor pattern IPX_TV2.

FIG. 8 is a schematic sectional view of a semiconductor structure according to some other exemplary embodiments of the present disclosure. The semiconductor structure SM20 illustrated in FIG. 8 is similar to the semiconductor structure SM10 illustrated in FIG. 5. Therefore, the same reference numerals are used to refer to the same or liked parts, and its detailed description will be omitted herein.

Referring to FIG. 8, in some embodiments, the semiconductor package PK2 obtained in FIG. 7A is mounted or attached onto a circuit substrate 400 through the conductive terminals 302B. Thereafter, passive devices PDX (integrated passive device or surface mount devices) may be mounted on the circuit substrate 400, and an underfill structure UX1 may be formed to surround the conductive post 302A and the conductive terminals 302B in the same way as described in FIG. 5. After bonding the semiconductor package PK2 on the circuit substrate 400 and forming the underfill structure UX1, the semiconductor structure SM20 in accordance with some embodiments of the present disclosure is accomplished.

In the semiconductor package PK2 illustrated in FIG. 7A and the semiconductor structure SM20 illustrated in FIG. 8, since a second inductor pattern IP2 and an auxiliary inductor pattern AP1 are electrically connected to the first inductor pattern IP1, and the inductor patterns (IP1, AP1, IP2) are stacked together to from a stacked inductor pattern, the inductance can be increased without excessive area sacrifice from the removal of the conductive layers/metal layers above and below the inductor pattern. In other words, the presence of the auxiliary inductor pattern AP1 and the second inductor pattern IP2 may occupy the originally empty area to gain inductance, which may also mitigate the uniformity/topography problem.

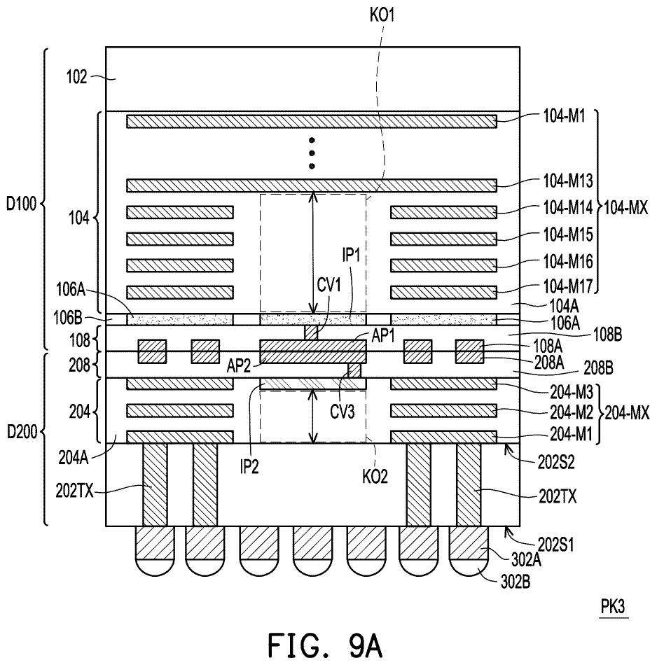

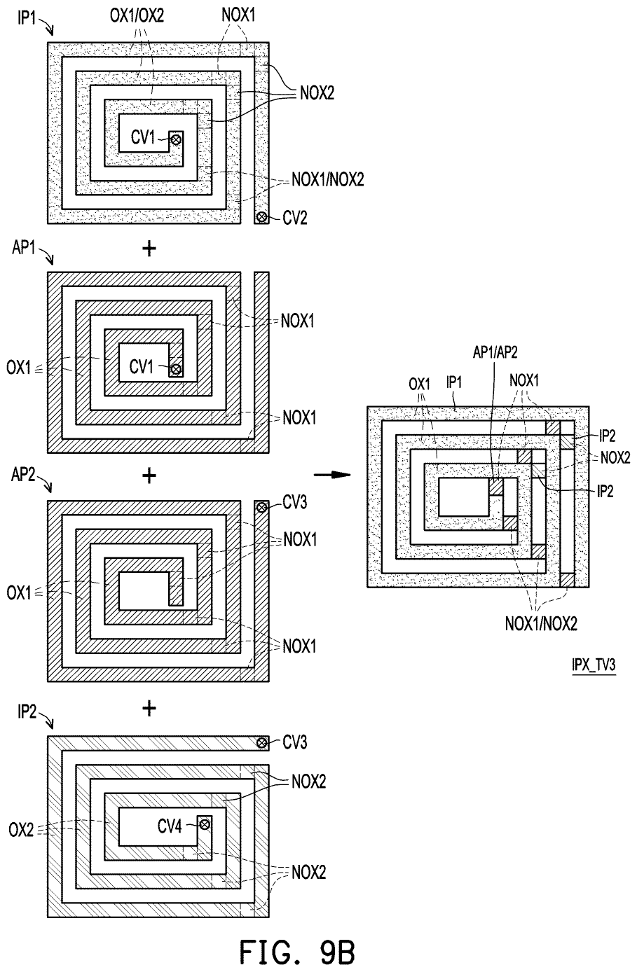

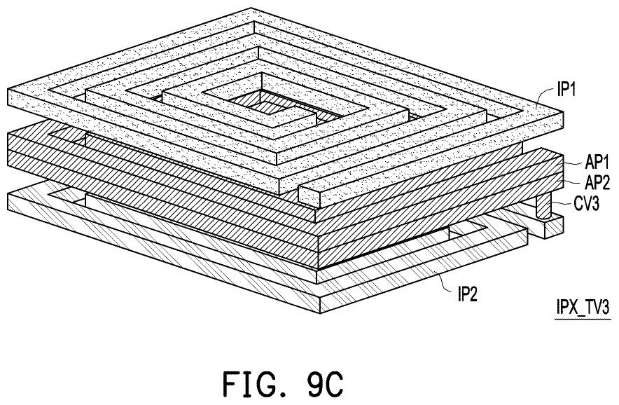

FIG. 9A is a schematic sectional view of a semiconductor package according to some other exemplary embodiments of the present disclosure. FIG. 9B is an exploded top view of stacked inductor patterns according to the semiconductor package illustrated in FIG. 9A. FIG. 9C is a three-dimensional view of stacked inductor patterns according to the semiconductor package illustrated in FIG. 9A. The semiconductor package PK3 and the stacked inductor pattern IPX_TV3 illustrated in FIG. 9A and FIG. 9B are similar to the semiconductor package PK1 and the stacked inductor pattern IPX_TV1 illustrated in FIG. 4 and FIG. 3B. Therefore, the same reference numerals are used to refer to the same or liked parts, and its detailed description will be omitted herein. The difference between the embodiments is in the arrangement of the inductor patterns (IP1, IP2) and the presence of an auxiliary inductor pattern AP1 and a second auxiliary inductor pattern AP2.

As illustrated in FIG. 9A to FIG. 9C, in some embodiments, the first bonding layer 108 in the first die D100 further includes an auxiliary inductor pattern AP1 that is joined with the first inductor pattern IP1. For example, the auxiliary inductor pattern AP1 is levelled with the first bonding pads 108A in the first bonding layer 108, and are made of the same materials with the first bonding pads 108A. In the exemplary embodiment, the conductive via CV1 is electrically connecting the first inductor pattern IP1 to the auxiliary inductor pattern AP1. Furthermore, the conductive via CV2 is electrically connecting the first inductor pattern IP1 to the seventeenth conductive layer 104-M17 in the first interconnection layer 104.

Furthermore, the second bonding layer 208 in the second die D200 further includes a second auxiliary inductor pattern AP2 that is joined with the second inductor pattern IP2. For example, the second auxiliary inductor pattern AP2 is located aside and levelled with the second bonding pads 208A, and are made of the same materials with the second bonding pads 208A. In the exemplary embodiment, the first die D100 is bonded to the second die D200 so that the auxiliary inductor pattern AP1 is directly bonded to the second auxiliary inductor pattern AP2 using direct metal-to-metal bonding. Furthermore, the conductive via CV3 is electrically connecting the second auxiliary inductor pattern AP2 to the second inductor pattern IP2, while the conductive via CV4 is electrically connecting the second inductor pattern IP2 to the second conductive layer 204-M2 in the second interconnection layer 204. In some embodiments, the auxiliary inductor pattern AP1 and the second auxiliary inductor pattern AP2 have the same inductor pattern design. In one embodiment, the auxiliary inductor pattern AP1 is fully overlapped with the second auxiliary inductor pattern AP2 in the stacking direction. For example, the coil turns and terminals of the auxiliary inductor pattern AP1 and the second auxiliary inductor pattern AP2 are matched and aligned with one another.

As further illustrated in FIG. 9B, the first inductor pattern IP1 is partially overlapped with the auxiliary inductor pattern AP1 and the second auxiliary inductor pattern AP2 to include overlapping regions OX1 and non-overlapping regions NOX1. The regions where the first inductor pattern IP1 are overlapped with the auxiliary inductor pattern AP1 and the second auxiliary inductor pattern AP2 in the stacking direction are defined as the overlapping regions OX1, while the regions where the first inductor pattern IP1 are non-overlapped with the auxiliary inductor pattern AP1 and the second auxiliary inductor pattern AP2 are defined as the non-overlapping regions NOX1. Similarly, the first inductor pattern IP1 are partially overlapped with the second inductor pattern IP2 to include overlapping regions OX2 and non-overlapping regions NOX2. The regions where the first inductor pattern IP1 are overlapped with the second inductor pattern IP2 in the stacking direction are defined as the overlapping regions OX2, while the regions where the first inductor pattern IP1 are non-overlapped with the second inductor pattern IP2 are defined as the non-overlapping regions NOX2.

In some embodiments, the first inductor pattern IP1, the auxiliary inductor pattern AP1, the second auxiliary inductor pattern AP2, and the second inductor pattern IP2 are all spiral inductor patterns having a rectangular shape, whereby sidewalls of the first inductor pattern IP1, the auxiliary inductor pattern AP1, the second auxiliary inductor pattern AP2, and the second inductor pattern IP2 are aligned with one another. However, a starting point and ending point of the terminals of the first inductor pattern IP1 are different from a starting point and ending point of the terminals of the auxiliary inductor pattern AP1 and the second auxiliary inductor pattern AP2. Similarly, a starting point and ending point of the terminals of the second inductor pattern IP2 are different from a starting point and ending point of the terminals of the auxiliary inductor pattern AP1 and the second auxiliary inductor pattern AP2. As such, the first inductor pattern IP1, the auxiliary inductor pattern AP1, the second auxiliary inductor pattern AP2, and the second inductor pattern IP2 are stacked over one another along the stacking direction to form the stacked inductor pattern IPX_TV3.

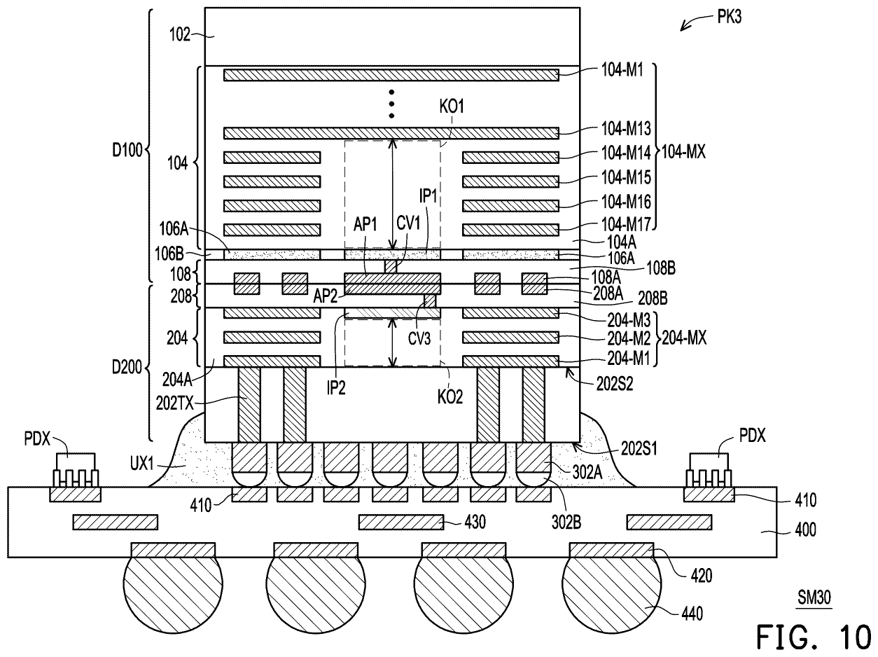

FIG. 10 is a schematic sectional view of a semiconductor structure according to some other exemplary embodiments of the present disclosure. The semiconductor structure SM30 illustrated in FIG. 10 is similar to the semiconductor structure SM10 illustrated in FIG. 5. Therefore, the same reference numerals are used to refer to the same or liked parts, and its detailed description will be omitted herein.

Referring to FIG. 10, in some embodiments, the semiconductor package PK3 obtained in FIG. 9A is mounted or attached onto a circuit substrate 400 through the conductive terminals 302B. Thereafter, passive devices PDX (integrated passive device or surface mount devices) may be mounted on the circuit substrate 400, and an underfill structure UX1 may be formed to surround the conductive post 302A and the conductive terminals 302B in the same way as described in FIG. 5. After bonding the semiconductor package PK3 on the circuit substrate 400 and forming the underfill structure UX1, the semiconductor structure SM30 in accordance with some embodiments of the present disclosure is accomplished.

In the semiconductor package PK3 illustrated in FIG. 9A and the semiconductor structure SM30 illustrated in FIG. 10, since a second inductor pattern IP2, an auxiliary inductor pattern AP1 and a second auxiliary inductor pattern AP2 are electrically connected to the first inductor pattern IP1, and the inductor patterns (IP1, AP1, AP2, IP2) are stacked together to from a stacked inductor pattern, the inductance can be increased without excessive area sacrifice from the removal of the conductive layers/metal layers above and below the inductor pattern. In other words, the presence of the auxiliary inductor pattern AP1, the second auxiliary inductor pattern AP2 and the second inductor pattern IP2 may occupy the originally empty area to gain inductance, which may also mitigate the uniformity/topography problem.

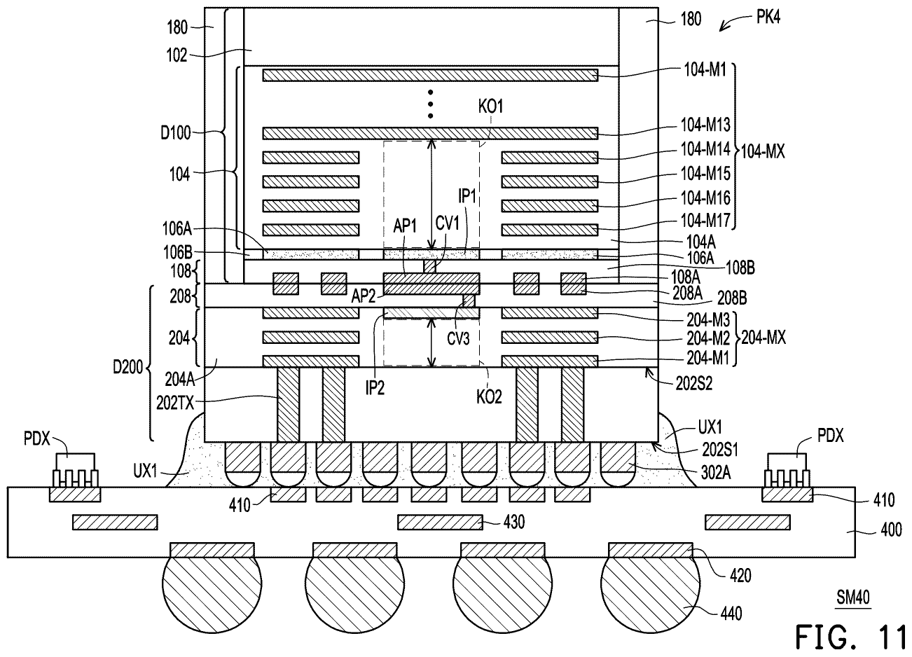

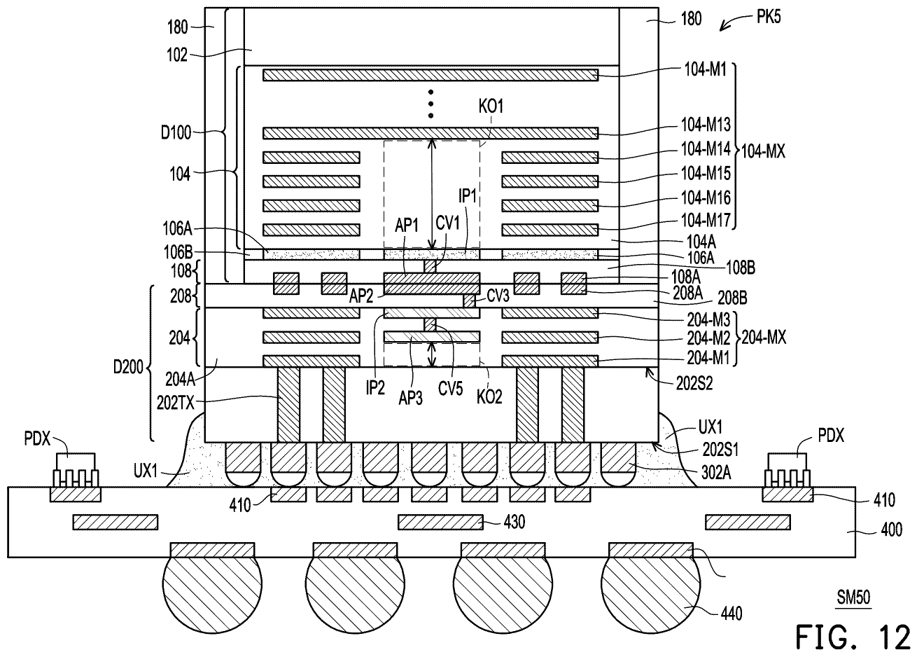

FIG. 11 is a schematic sectional view of a semiconductor structure according to some other exemplary embodiments of the present disclosure. The semiconductor structure SM40 illustrated in FIG. 11 is similar to the semiconductor structure SM30 illustrated in FIG. 10. Therefore, the same reference numerals are used to refer to the same or liked parts, and its detailed description are omitted herein.

In the previous embodiments, the first die D100 is stacked on the second die D200 to form a semiconductor package in a way that the sidewalls of the first die D100 are aligned with sidewalls of the second die D200. However, the disclosure is not limited thereto. In the embodiment illustrated in FIG. 11, in the semiconductor package PK4, a lateral dimension of the first die D100 is smaller than a lateral dimension of the second die D200. Therefore, after bonding the first die D100 to the second die D200 to form the semiconductor package PK4, the sidewalls of the first die D100 are misaligned with sidewalls of the second die D200.

In some embodiments, forming the semiconductor package PK4 further includes forming a gap-filling layer or encapsulant 180 to surround the first die D100. For example, a material of the encapsulant 180 includes polymers (such as epoxy resins, phenolic resins, silicon-containing resins, or other suitable resins), dielectric materials having low permittivity (Dk) and low loss tangent (Df) properties, or other suitable materials. In an alternative embodiment, the encapsulant 180 may include an acceptable insulating encapsulation material. In some embodiments, the encapsulant 180 may further include inorganic filler or inorganic compound (e.g. silica, clay, and so on) which can be added therein to optimize coefficient of thermal expansion (CTE) of the encapsulant 180. The disclosure is not limited thereto. After forming the encapsulant 180 to surround the first die D100, sidewalls of the encapsulant 180 are aligned with the sidewalls of the second die D200.

As further illustrated in FIG. 11, after forming the semiconductor package PK4, and placing the semiconductor package PK4 onto a circuit substrate 400, passive devices PDX (integrated passive device or surface mount devices) may be mounted on the circuit substrate 400, and an underfill structure UX1 may be formed to surround the conductive post 302A and the conductive terminals 302B in the same way as described in FIG. 5. As such, the semiconductor structure SM40 in accordance with some embodiments of the present disclosure is accomplished.

In the semiconductor structure SM40 illustrated in FIG. 11, since a second inductor pattern IP2, an auxiliary inductor pattern AP1 and a second auxiliary inductor pattern AP2 are electrically connected to the first inductor pattern IP1, and the inductor patterns (IP1, AP1, AP2, IP2) are stacked together to from a stacked inductor pattern, the inductance can be increased without excessive area sacrifice from the removal of the conductive layers/metal layers above and below the inductor pattern. In other words, the presence of the auxiliary inductor pattern AP1, the second auxiliary inductor pattern AP2 and the second inductor pattern IP2 may occupy the originally empty area to gain inductance, which may also mitigate the uniformity/topography problem.

FIG. 12 is a schematic sectional view of a semiconductor structure according to some other exemplary embodiments of the present disclosure. The semiconductor structure SM50 illustrated in FIG. 12 is similar to the semiconductor structure SM40 illustrated in FIG. 11. Therefore, the same reference numerals are used to refer to the same or liked parts, and its detailed description are omitted herein. The difference between the embodiments is that the semiconductor structure SM50 illustrated in FIG. 12 further includes a third auxiliary inductor pattern AP3 in the semiconductor package PK5.

As illustrated in FIG. 12, in the exemplary embodiment, the second inductor pattern IP2 is further connected to the third auxiliary inductor pattern AP3 through a conductive via CV5. For example, the third auxiliary inductor pattern AP3 is formed to be levelled with the second conductive layer 204-M2, and are formed of the same materials with the second conductive layer 204-M2. In such embodiment, a height of the second keep out zone KO2 is approximately equal to a height of one conductive layer (e.g. the first conductive layer 204-M1) of the plurality of second conductive layers 204-MX. Furthermore, in the exemplary embodiment, the auxiliary inductor pattern AP1 and the second auxiliary inductor pattern AP2 have the same matched and aligned inductor patterns, while the first inductor pattern IP1, the second inductor pattern IP2 and the third auxiliary inductor pattern AP3 have inductor patterns that are not matched and aligned with one another.

In the semiconductor structure SM50 illustrated in FIG. 12, since a second inductor pattern IP2, an auxiliary inductor pattern AP1, a second auxiliary inductor pattern AP2 and a third auxiliary inductor pattern AP3 are electrically connected to the first inductor patternIP1, and the inductor patterns (IP1, AP1, AP2, AP3, IP2) are stacked together to from a stacked inductor pattern, the inductance can be further increased without excessive area sacrifice from the removal of the conductive layers/metal layers above and below the inductor pattern. In other words, the presence of the auxiliary inductor pattern AP1, the second auxiliary inductor pattern AP2, the third auxiliary inductor pattern AP3, and the second inductor pattern IP2 may occupy the originally empty area to gain inductance, which may also mitigate the uniformity/topography problem.

In the above embodiments, the semiconductor structure at least includes a second inductor pattern electrically connected to a first inductor pattern, whereby the second inductor pattern is directly overlapped with the first inductor pattern. As such, the presence of an extra inductor pattern will replace the position of the conductive layers/metal layers of the interconnection layer originally located beneath and above a single inductor pattern. Therefore, the degradation in the inductor performance due to magnetic field/flux caused by the conductive layers/metal layers may be reduced. Furthermore, removal of conductive layers/metal layers on one side of the inductor pattern, and physically connecting the other side of the inductor pattern to another inductor pattern will further improve inductor performance. In other words, with the stacked inductor pattern design, the inductance can be further increased without excessive area sacrifice from the removal of the conductive layers/metal layers above and below the inductor pattern, and the uniformity/topography problem is also resolved.

In accordance with some embodiments of the present disclosure, a semiconductor structure includes a first die and a second die. The first die includes a first substrate, a first interconnection layer, a first inductor pattern and a first bonding layer. The first interconnection layer is disposed on the first substrate. The first inductor pattern is disposed on and electrically connected to the first interconnection layer. The first bonding layer includes first bonding pads. The second die is bonded to the first die, and includes a second substrate, a second interconnection layer, a second inductor pattern and a second bonding layer. The second interconnection layer is disposed on the second substrate. The second inductor pattern is disposed on and electrically connected to the second interconnection layer. The second bonding layer includes second bonding pads, wherein the second bonding pads are joined with the first bonding pads, and wherein the first inductor pattern is electrically connected to the second inductor pattern through the first bonding layer and the second bonding layer.

In accordance with some other embodiments of the present disclosure, a semiconductor structure includes a circuit substrate, a top die and an interposer die. The top die is disposed on and electrically connected to the circuit substrate, wherein the top die includes a first interconnection layer, a first inductor pattern. The first interconnection layer includes a plurality of conductive layers and a plurality of dielectric layers that are alternately stacked, wherein the first interconnection layer includes a first keep out zone that is free of the plurality of conductive layers. The first inductor pattern is disposed on the first interconnection layer and over the first keep out zone. The interposer die is electrically connecting the top die to the circuit substrate, wherein the interposer die includes a second interconnection layer and a second inductor pattern. The second interconnection layer includes a plurality of second conductive layers and a plurality of second dielectric layers that are alternately stacked, wherein the second interconnection layer comprises a second keep out zone that is free of the plurality of second conductive layers. The second inductor pattern is disposed on the second interconnection layer and over the second keep out zone, wherein the second inductor pattern is electrically connected to the first inductor pattern of the top die.

In accordance with yet another embodiment of the present disclosure, a method of fabricating a semiconductor structure is described. The method includes the following steps. A first die is formed, wherein forming the first die includes forming a first interconnection layer on a first substrate; forming a first inductor pattern disposed on and electrically connected to the first interconnection layer; and forming a first bonding layer on the first inductor pattern, wherein the first bonding layer comprises a plurality of first bonding pads. A second die is formed, wherein forming the second die includes forming a second interconnection layer on a second substrate; and forming a second inductor pattern electrically connected to the second interconnection layer, and forming a second bonding layer on the second interconnection layer, wherein the second bonding layer comprises a plurality of second bonding pads. The method further includes bonding the first die to the second die by joining the plurality of first bonding pads to the plurality of second bonding pads, wherein the first inductor pattern is electrically connected to the second inductor pattern through the first bonding layer and the second bonding layer.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor structure, comprising:
a first die, comprising:
a first substrate;
a first interconnection layer disposed on the first substrate;
a first inductor pattern disposed on and electrically connected to the first interconnection layer; and
a first bonding layer comprising a plurality of first bonding pads;
a second die bonded to the first die, and comprising:
a second interconnection layer;
a second inductor pattern disposed on and electrically connected to the second interconnection layer; and
a second bonding layer comprising a plurality of second bonding pads, wherein the plurality of second bonding pads is joined with the plurality of first bonding pads, and wherein the first inductor pattern is electrically connected to the second inductor pattern through the first bonding layer and the second bonding layer.

2. The semiconductor structure according to claim 1, wherein the first inductor pattern and the second inductor pattern are partially overlapped with one another to include an overlapping region and a non-overlapping region.

3. The semiconductor structure according to claim 1, wherein the first inductor pattern and the second inductor pattern are spiral inductor patterns having a rectangular shape, a circular shape, an octagonal shape, or a hexagonal shape.

4. The semiconductor structure according to claim 1, wherein the first inductor pattern is directly joined with one of the plurality of first bonding pads through a conductive via.

5. The semiconductor structure according to claim 1, wherein the second inductor pattern is embedded in the second bonding layer and located aside the plurality of second bonding pads, and wherein the first bonding layer further comprises an auxiliary inductor pattern that is bonded to the second inductor pattern.

6. The semiconductor structure according to claim 1, wherein the first bonding layer further comprises an auxiliary inductor pattern that is joined with the first inductor pattern, and the second bonding layer further comprises a second auxiliary inductor pattern that is joined with the second inductor pattern, and wherein the auxiliary inductor pattern is bonded to the second auxiliary inductor pattern.

7. The semiconductor structure according to claim 1, wherein the second die further comprises a plurality through substrate vias electrically connected to the second interconnection layer, and wherein the semiconductor structure further comprises a plurality of conductive terminals disposed on and electrically connected to the plurality of through substrate vias.

8. A semiconductor structure, comprising:
a circuit substrate;
a top die disposed on and electrically connected to the circuit substrate, wherein the top die comprises:
a first interconnection layer comprising a plurality of conductive layers and a plurality of dielectric layers that are alternately stacked, wherein the first interconnection layer comprises a first keep out zone that is free of the plurality of conductive layers; and
a first inductor pattern disposed on the first interconnection layer and over the first keep out zone;
an interposer die electrically connecting the top die to the circuit substrate, wherein the interposer die comprises:
a second interconnection layer comprising a plurality of second conductive layers and a plurality of second dielectric layers that are alternately stacked, wherein the second interconnection layer comprises a second keep out zone that is free of the plurality of second conductive layers; and
a second inductor pattern disposed on the second interconnection layer and over the second keep out zone, wherein the second inductor pattern is electrically connected to the first inductor pattern of the top die.

9. The semiconductor structure according to claim 8, wherein the top die further comprises a first bonding layer comprising a plurality of first bonding pads, and the interposer die further comprises a second bonding layer comprising a plurality of second bonding pads, wherein the plurality of second bonding pads is bonded to the plurality of first bonding pads, and wherein the first inductor pattern is electrically connected to the second inductor pattern through the first bonding layer.

10. The semiconductor structure according to claim 9, wherein the first bonding layer further comprises an auxiliary inductor pattern that is joined with the first inductor pattern, and the second bonding layer further comprises a second auxiliary inductor pattern that is joined with the second inductor pattern, and wherein the auxiliary inductor pattern is bonded to the second auxiliary inductor pattern.

11. The semiconductor structure according to claim 9, wherein the first inductor pattern is connected to one of the plurality of first bonding pads through a first conductive via, and the second inductor pattern is connected to one of the plurality of second bonding pads through a second conductive via, wherein the first conductive via is vertically aligned with the second conductive via.

12. The semiconductor structure according to claim 9, wherein the first bonding layer further comprises an auxiliary inductor pattern that is joined with the first inductor pattern, and wherein the second inductor pattern is embedded in the second bonding layer aside the plurality of second bonding pads, and the second inductor pattern is bonded to the auxiliary inductor pattern.

13. The semiconductor structure according to claim 8, wherein a height of the first keep out zone is equal to or greater than a total height of four conductive layers of the plurality of conductive layers, and a height of the second keep out zone is equal to or greater than a height of one conductive layer of the plurality of second conductive layers.

14. The semiconductor structure according to claim 8, further comprising a plurality of through substrate vias electrically connecting the second interconnection layer to the circuit substrate.

15. The semiconductor structure according to claim 14, wherein the interposer die is electrically connected to the circuit substrate through a plurality of conductive terminals disposed on the plurality of through substrate vias, and wherein the semiconductor structure further comprises an underfill structure covering the plurality of conductive terminals.

16. A method of fabricating a semiconductor structure, comprising
forming a first die, comprising:
forming a first interconnection layer on a first substrate;
forming a first inductor pattern disposed on and electrically connected to the first interconnection layer; and
forming a first bonding layer on the first inductor pattern, wherein the first bonding layer comprises a plurality of first bonding pads;
forming a second die, comprising:
forming a second interconnection layer; and
forming a second inductor pattern electrically connected to the second interconnection layer, and forming a second bonding layer on the second interconnection layer, wherein the second bonding layer comprises a plurality of second bonding pads;
bonding the first die to the second die by joining the plurality of first bonding pads to the plurality of second bonding pads, wherein the first inductor pattern is electrically connected to the second inductor pattern through the first bonding layer and the second bonding layer.

17. The method according to claim 16, wherein after bonding the first die to the second die, the first inductor pattern is partially overlapped with the second inductor pattern to include an overlapping region and a non-overlapping region.

18. The method according to claim 16, wherein the second inductor pattern is formed in the second bonding layer and formed aside the plurality of second bonding pads, and forming the first bonding layer further comprises forming an auxiliary inductor pattern, wherein during bonding the first die to the second die, the auxiliary inductor pattern is directly bonded to the second inductor pattern.

19. The method according to claim 16, wherein forming the first bonding layer further comprises forming an auxiliary inductor pattern that is joined with the first inductor pattern, and forming the second bonding layer further comprises forming a second auxiliary inductor pattern that is joined with the second inductor pattern, and wherein during bonding the first die to the second die, the auxiliary inductor pattern is bonded to the second auxiliary inductor pattern.

20. The method according to claim 16, wherein forming the second die further comprises forming a plurality through substrate vias electrically connected to the second interconnection layer, and the method further comprises forming a plurality of conductive terminals disposed on and electrically connected to the plurality of through substrate vias.
